(19) United States
(12) Patent Application Publication
(10) Pub. No.: US 2023/0375278 A1
(43) Pub. Date: Nov. 23, 2023

(54) HEAT PIPE

(71) Applicant: Furukawa Electric Co., Ltd., Tokyo (JP)

(72) Inventor: Yasumi SASAKI, Tokyo (JP)

(73) Assignee: Furukawa Electric Co., Ltd., Tokyo (JP)

(21) Appl. No.: 18/361,602

(22) Filed: Jul. 28, 2023

Related U.S. Application Data
(63) Continuation of application No. PCT/JP2022/006060, filed on Feb. 16, 2022.

(30) Foreign Application Priority Data
Mar. 5, 2021 (JP) 2021-035356

(51) Int. Cl. F28D 15/04; F28D 15/02

(52) U.S. Cl. CPC F28D 15/04; F28D 15/0233

(57) ABSTRACT

A heat pipe including a container being a tubular body, the container having an end surface of one end portion and an end surface of another end portion, the end surfaces each being sealed; a wick structure provided inside the container; and a working fluid enclosed inside the container. The wick structure includes a first wick portion and a second wick portion in at least one cross section perpendicular to a longitudinal direction of the container, the second wick portion being integral with the first wick portion, the second wick portion extending outward from the first wick portion, the second wick portion being thinner than the first wick portion, and the second wick portion includes a flat portion extending in a direction perpendicular to a height direction of the internal space of the container.

### CROSS REFERENCE TO RELATED APPLICATIONS

The present application is a continuation application of International Patent Application No. PCT/JP2022/006060 filed on Feb. 16, 2022, which claims the benefit of Japanese Patent Application No. 2021-035356, filed on Mar. 5, 2021. The contents of these applications are incorporated herein by reference in their entirety.

### BACKGROUND

### Technical Field

The present disclosure relates to a heat pipe that has excellent flow characteristics for working fluid, exhibits excellent heat transport characteristics, and is capable of preventing abnormal noise from being generated when the working fluid flows.

### Background

Electronic components such as semiconductor elements installed in electrical and electronic devices such as laptop computers and servers generate more heat due to higher functionality, and cooling is becoming more important. Heat pipes are sometimes used as a unit configured to cool electronic components. In addition, downsizing of electric and electronic devices is increasingly making internal spaces of the electric and electronic devices smaller and narrower, so that further downsizing of heat pipes is also required. Therefore, thin heat pipes, which are made by flattening containers of heat pipes, are sometimes used.

In addition, thin heat pipes that have been flattened are sometimes required to reliably maintain the internal spaces, which have been depressurized, to reliably provide flow paths of the working fluid. Therefore, a heat pipe has been proposed in which at least one stay, having a height that prevents a container body from being deformed to be flatter, is fixed in the longitudinal direction at the center of the inside of a flat container body, and a wick for working liquid circular current is integrally laid with a thickness lower than the height of the stay in one half of the inside of the container body (Japanese Patent Laid-Open No. 2002-213887). In Japanese Patent Laid-Open No. 2002-213887, a stay is erected inside the container that has been flattened to prevent the container from being deformed to be flatter and reliably provide a flow path for the working fluid.

However, in Japanese Patent Laid-Open No. 2002-213887, the stay, which is a member different from the wick structure, is provided in the internal space of the heat pipe, so that the installation amount of the wick structure reduces and also the vapor flow path, through which working fluid in gas-phase flows, reduces. Further, in Japanese Patent Laid-Open No. 2002-213887, the wick structure extends over the entire width direction of the flat container, so that the vapor flow path also reduces. Therefore, in Japanese Patent Laid-Open No. 2002-213887, it is not possible to sufficiently obtain flow characteristics of the working fluid. Further, in Japanese Patent Laid-Open No. 2002-213887, it is not possible to sufficiently obtain flow characteristics of the working fluid, so that it is not possible to sufficiently obtain the maximum heat transport amount and to exhibit excellent heat transport characteristics.

Furthermore, as in Japanese Patent Laid-Open No. 2002-213887, when sufficient working fluid flow characteristics cannot be obtained, the working fluid in liquid-phase may accumulate in the vapor flow path of the condenser portion of the heat pipe. In addition, when the wick structure is provided only in the central portion in the width direction of the container to reliably provide the vapor flow path, the working fluid in liquid-phase may accumulate in the vapor flow path at end portions in the width direction of the container, in the condenser portion of the heat pipes. In particular, when the condenser portion of the heat pipe is positioned on the lower side in the gravity direction, the working fluid in liquid-phase is likely to accumulate in the vapor flow path of the condenser portion of the heat pipe.

For example, when the installation posture of an electric and electronic device such as a laptop computer is changed to move the condenser portion upward in the gravity direction in a state in which the working fluid in liquid-phase accumulates in the vapor flow path of the condenser portion positioned on the lower side in the gravity direction, the working fluid in liquid-phase accumulating in the condenser portion flows downward in the gravity direction. The working fluid in liquid-phase flowing downward in the gravity direction may cause the working fluid in liquid-phase to collide with the working fluid in gas-phase flowing through the vapor flow path from the evaporator portion of the heat pipe to the condenser portion on the upper side in the gravity direction, and thereby the working fluid in liquid-phase is blown away by the working fluid in gas-phase, so that abnormal noise occurs.

Further, the working fluid in liquid-phase accumulating in the vapor flow path of the condenser portion flows downward in the gravity direction and collide with the working fluid in gas-phase, and thereby pressure loss occurs in flow of the working fluid in gas-phase, so that the working fluid cannot exhibit excellent heat transport characteristics.

The present disclosure is related to providing a heat pipe that has excellent flow characteristics of working fluid, exhibits excellent heat transport characteristics, and is capable of preventing abnormal noise from being generated when the working fluid flows.

### SUMMARY

The gist of the configuration of the present disclosure is as follows.

{1} A heat pipe including:
a container being a tubular body, the container having an end surface of one end portion and an end surface of another end portion, the end surfaces each being sealed;
a wick structure provided inside the container; and
a working fluid enclosed inside the container,
wherein the wick structure includes a first wick portion and a second wick portion in at least one cross section perpendicular to a longitudinal direction of the container, the second wick portion being integral with the first wick portion, the second wick portion extending outward from the first wick portion, the second wick portion being thinner than the first wick portion, and
the second wick portion includes a flat portion extending in a direction perpendicular to a height direction of an internal space of the container.

{2} The heat pipe according to {1}, wherein the first wick portion has a thickness of 50% or more of a height of the internal space of the container, and the second wick portion has a thickness of less than 50% of the height of the internal space of the container.

{3} The heat pipe according to {1} or {2}, wherein at least a partial area of the container has a flattened portion subjected to flattening processing.

{4} The heat pipe according to {3}, wherein the flattened portion includes one inner surface and another inner surface facing the one inner surface in the height direction of the internal space of the container, and in the one cross section, the first wick portion has a top portion in contact with the one inner surface and a bottom portion in contact with the other inner surface.

{5} The heat pipe according to any one of {1} to {4}, wherein, in the one cross section, the wick structure has a gradual change portion between a top portion of the first wick portion and the flat portion, the gradual change portion being a portion in which thickness of the wick structure continuously reduces in a direction perpendicular to the height direction of the internal space of the container.

{6} The heat pipe according to any one of {1} to {5}, wherein, in the one cross section, a ratio of a width of the second wick portion with respect to a sum of the width of the second wick portion and a width from an end of the second wick portion to an inner surface of the container is 50% or more, the inner surface facing the end of the second wick portion which is in contact with the inner surface or is not in contact with the inner surface.

{7} The heat pipe according to any one of {1} to {6}, wherein an end of the second wick portion is not in contact with an inner surface of the container facing the end of the second wick portion.

{8} The heat pipe according to any one of {1} to {7}, wherein in the one cross section, a ratio of a cross-sectional area of the second wick portion to a cross-sectional area of the first wick portion is 1.0% or more and 50% or less.

{9} The heat pipe according to any one of {1} to {8}, wherein the container has an evaporator portion and a condenser portion, and a thickness of the flat portion in the evaporator portion is thicker than a thickness of the flat portion in the condenser portion, the evaporator portion being thermally connected to a heating element, the condenser portion being thermally connected to a unit configured to exchange heat.

{10} The heat pipe according to any one of {1} to {9}, wherein, in the one cross section, a ratio of a cross-sectional area of the internal space of the container not occupied by the wick structure with respect to a cross-sectional area of the wick structure is 15% or more and 65% or less.

{11} The heat pipe according to any one of {1} to {10}, wherein the wick structure is a sintered body of metal powder.

The “flat portion” of the second wick portion in the above aspect means a region where the thickness change rate of the second wick portion is 5.0% or less of the height of the internal space of the container, in a direction perpendicular to the height direction of the internal space of the container (hereinafter, sometimes referred to as “the width direction of the internal space of the container”). Further, the “gradual change portion” of the wick structure in the above aspects means a region where the change rate of the thickness of the wick structure with respect to the unit length in the width direction of the internal space of the container exceeds 5.0% of the height of the internal space of the container in the width direction of the internal space of the container.

In accordance with the aspects of the heat pipe of the present disclosure, the wick structure has a first wick portion and a second wick portion that is thinner than the first wick portion, that is, has the first wick portion relatively thick in the height direction of the internal space of the container, and thereby has excellent characteristics of circular current, of the working fluid in liquid-phase, from the condenser portion to the evaporator portion. Further, in accordance with the aspects of the heat pipe of the present disclosure, the second wick portion, which extends outward from the first wick portion and is relatively thin in the height direction of the internal space of the container, has a flat portion that extends in the width direction of the internal space of the container, and thereby sufficiently provides the vapor flow path through which the working fluid in gas-phase flows and causes the working fluid in liquid-phase to be absorbed by the wick structure due to the capillary force of the flat portion. Therefore, the second wick portion having the flat portion makes it possible to prevent the working fluid in liquid-phase from accumulating at the end portion in the width direction of the internal space of the container, in the condenser portion of the heat pipe. From the above, in accordance with the aspects of the heat pipe of the present disclosure, the heat pipe has excellent flow characteristics of the working fluid, exhibits excellent heat transport characteristics, and is capable of preventing abnormal noise from being generated when the working fluid flows even if the installation posture of the electric or electronic device equipped with the heat pipe of the present disclosure changes. Further, in accordance with the aspects of the heat pipe of the present disclosure, the wick structure has a first wick portion having a thickness of 50% or more of the height of the internal space of the container, and thereby has further excellent characteristics of circular current, of the working fluid in liquid-phase, from the condenser portion to the evaporator portion. In addition, in accordance with the aspects of the heat pipe of the present disclosure, a second wick portion, which extends outward from the first wick portion with a thickness of 50% or more of the height of the internal space of the container and has a thickness less than 50% of the height of the internal space of the container, has a flat portion extending in the width direction of the internal space of the container, and thereby further sufficiently provides the vapor flow path through which the working fluid in gas-phase flows and causes the working fluid in liquid-phase to be absorbed by the wick structure due to the capillary force of the flat portion. So, the second wick portion having a thickness of less than 50% of the height of the internal space of the container has a flat portion, and this makes it possible to prevent the working fluid in liquid-phase from accumulating in the end portion in the width direction of the internal space of the container in the condenser portion of the heat pipe. From the above, in accordance with the aspects of the heat pipe of the present disclosure, the heat pipe has further excellent flow characteristics of the working fluid, exhibits further excellent heat transport characteristics, and is capable of preventing abnormal noise from being generated when the working fluid flows even if the installation posture of the electric or electronic device equipped with the heat pipe of the present disclosure changes.

In accordance with the aspects of the heat pipe of the present disclosure, the first wick portion has the top portion in contact with the one inner surface of the container and the bottom portion in contact with the other inner surface of the container, so that characteristics of circular current, of the working fluid in liquid-phase, from the condenser portion to the evaporator portion reliably improves.

In accordance with the aspects of the heat pipe of the present disclosure, the ratio of the width of the second wick portion with respect to the sum of the width of the second wick portion and the width from the end of the second wick portion to the inner surface, of the container, facing the end of the second wick portion which is in contact with the inner surface or is not in contact with the inner surface is 50% or more. This makes it possible to more reliably prevent the working fluid in liquid-phase from accumulating at the end portion in the width direction of the internal space of the container.

In accordance with the aspects of the heat pipe of the present disclosure, since the end of the second wick portion is not in contact with the inner surface, of the container, facing the end of the second wick portion, the vapor flow path is more reliably provided, so that the flow characteristics of the working fluid in gas-phase further improve.

In accordance with the aspects of the heat pipe of the present disclosure, the ratio of the cross-sectional area of the second wick portion to the cross-sectional area of the first wick portion is 1.0% or more and 50% or less, and this makes it possible to improve the excellent flow characteristics of the working fluid and the prevention of abnormal noise when the flow of the working fluid flows in a well-balanced manner.

In accordance with the aspects of the heat pipe of the present disclosure, the thickness of the flat portion of the second wick portion in the evaporator portion is thicker than the thickness of the flat portion in the condenser portion, so that the capillary force of the second wick portion in the evaporator portion improves more. Therefore, the characteristics of circular current, of the working fluid in liquid-phase, from the condenser portion to the evaporator portion improves more.

In accordance with the aspects of the heat pipe of the present disclosure, the ratio of the cross-sectional area of the internal space of the container not occupied by the wick structure with respect to the cross-sectional area of the wick structure is 10% or more and 50% or less. This makes it possible to improve the flow characteristics of the working fluid in liquid-phase and the flow characteristics of the working fluid in gas-phase in a well-balanced manner.

### BRIEF DESCRIPTION OF THE DRAWINGS

FIG. 1 is an explanatory view showing an outline of a cross section in a longitudinal direction of a heat pipe according to a first example embodiment of the present disclosure;

FIG. 2 is an explanatory view showing an outline of a cross section in a direction perpendicular to the longitudinal direction of the heat pipe according to the first example embodiment of the present disclosure;

FIG. 3 is an explanatory view showing an outline of a cross section in a longitudinal direction of a heat pipe according to a second example embodiment of the present disclosure;

FIG. 4 is an explanatory view showing an outline of a cross section in a longitudinal direction of a heat pipe according to a third example embodiment of the present disclosure; and

FIG. 5 is an explanatory view showing an outline of a cross section in a longitudinal direction of a heat pipe according to a fourth example embodiment of the present disclosure.

### DETAILED DESCRIPTION

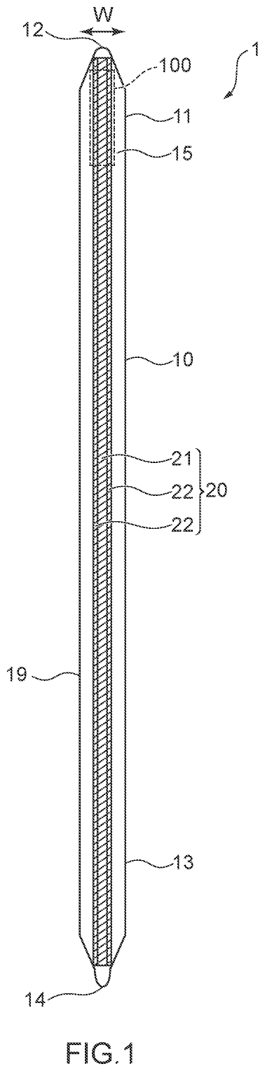

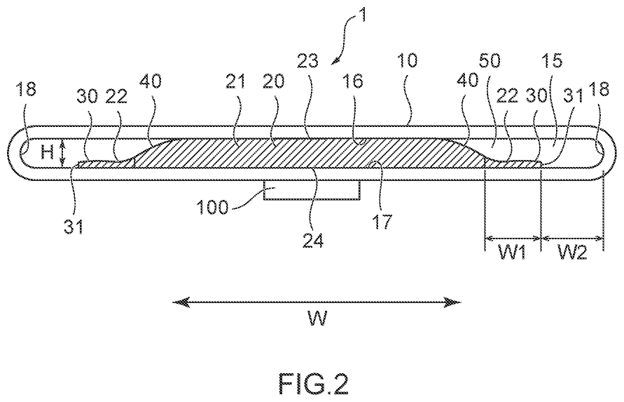

Hereinafter, a heat pipe according to a first example embodiment of the present disclosure will be described with reference to the accompanying drawings. FIG. 1 is an explanatory view showing an outline of a cross section in a longitudinal direction of the heat pipe according to a first example embodiment of the present disclosure. FIG. 2 is an explanatory view showing an outline of a cross section in a direction perpendicular to the longitudinal direction of the heat pipe according to the first example embodiment of the present disclosure.

As shown in FIG. 1, a heat pipe 1 according to the first example embodiment of the present disclosure includes a container 10, which is a tubular body, having an end surface 12 of one end portion 11 sealed and having an end surface 14 of another end portion 13 sealed, a wick structure 20 provided inside the container 10, and a working fluid (not shown) enclosed inside the container 10. The container 10 has a long shape. The shape of the container 10 in the longitudinal direction can be appropriately selected according to use conditions and the like, and may be linear or may have curved portions. Here, the heat pipe 1 is linear for convenience of explanation. Further, the inside of the container 10 is a sealed space that has been depressurized.

The wick structure 20 extends in the longitudinal direction of the container 10 from the one end portion 11 to another end portion 13 of the container 10. Also, the width of the wick structure 20 extends in the longitudinal direction of the container 10 with substantially the same dimension. For example, the heat pipe 1 functions as an evaporator portion with the one end portion 11 being thermally connected to a heating element 100, and functions as a condenser portion with the other end portion 13 being thermally connected to a unit configured to exchange heat (not shown). From the above, the wick structure 20 extends in the heat transport direction of the heat pipe 1.

The cross-sectional shape in the direction perpendicular to the longitudinal direction of the container 10 is not particularly limited. Here, as shown in FIG. 2, the heat pipe 1 has a flat shape subjected to flattening processing. Therefore, the heat pipe 1 is a thin heat pipe having a flattened portion. The wall thickness of the container 10 is not particularly limited, and is, for example, 0.1 mm to 0.5 mm. The height H of the internal space 15 of the container 10 is not particularly limited, and is, for example, 0.5 mm to 2.0 mm. The dimension of the internal space 15 of the container 10 in the direction perpendicular to the direction of the height H (that is, the width direction W of the internal space 15 of the container 10) is not particularly limited, and is, for example, 5 mm to 30 mm.

As shown in FIG. 2, in a cross section perpendicular to the longitudinal direction of the container 10, the wick structure 20 includes a first wick portion 21 having a predetermined thickness and second wick portions 22 each having a thinner thickness than the first wick portion 21. Therefore, in the cross section, the first wick portion 21 is thicker than the second wick portions 22. The wick structure 20 just needs to have a first wick portion 21 which is a relatively thick region and second wick portions 22 which are relatively thin regions in the cross section. In the heat pipe 1, in a cross section perpendicular to the longitudinal direction of the container 10, the wick structure 20 has the first wick portion 21 with a thickness of 50% or more of the height H of the internal space 15 of the container 10 and the second wick portions 22 each with a thickness of less than 50% of the height H of the internal space 15 of the container 10. The second wick portions 22 are integral with the first wick portion 21 and extend outward from the first wick portion 21. In the above cross section, the heat pipe 1 is provided with the first wick portion 21 in the central portion in the width direction W of the internal space 15 of the container 10, and the second wick portions 22 continuously on both sides of the first wick portion 21. The second wick portions 22 are provided near both end portions in the width direction W of the internal space 15 of the container 10.

The flattened portion of the container 10 has one inner surface 16 and the other inner surface 17 facing the one inner surface 16 in the height H direction of the internal space 15 of the container 10. The first wick portion 21 has a top portion 23 in contact with one inner surface 16 and a bottom portion 24 in contact with the other inner surface 17. Therefore, in the heat pipe 1, the first wick portion 21 includes a region with a thickness corresponding to the height H of the internal space 15 of the container 10, that is, a thickness of 100% of the height H of the internal space 15 of the container 10. From the above, the thickness of the region corresponding to the top portion 23 of the first wick portion 21 maintains the thickness corresponding to the height H of the internal space 15. In the heat pipe 1, the top portion 23 of the first wick portion 21 is in surface contact with one inner surface 16, and the bottom portion 24 of the first wick portion 21 is in surface contact with the other inner surface 17.

The second wick portions 22 are provided in contact with the other inner surface 17, and are not in contact with the one inner surface 16 and side inner surfaces 18 connecting the one inner surface 16 and the other inner surface 17. Therefore, the second wick portions 22 are not provided on the one inner surface 16 and the side inner surface 18. A region, of the one inner surface 16, that is not in contact with the first wick portion 21 and the side inner surfaces 18 are both exposed to the internal space 15.

The second wick portions 22 each have a flat portion 30 extending in the width direction W of the internal space 15 of the container 10. The flat portion 30 is formed at both end portions of the second wick portion 22 in the width direction W of the internal space 15. The flat portion 30 extends from the first wick portion 21 toward the side inner surface 18 over a predetermined length while maintaining a predetermined thickness that is less than 50% of the height H of the internal space 15. The flat portion 30 maintains a predetermined thickness of less than 50% of the height H of the internal space 15. However, from the point of sufficiently providing the vapor flow path 50 through which the working fluid in gas-phase flows and reliably preventing the working fluid in liquid-phase from accumulating, it is preferable to maintain a predetermined thickness of less than 30% of the height H of the internal space 15, and it is particularly preferable to maintain a predetermined thickness of less than 20% of the height H of the internal space 15. On the other hand, from the point of reliably preventing the working fluid in liquid-phase from accumulating at the end portion in the width direction W of the internal space 15 of the container 10, it is preferable for the flat portion 30 to maintain a predetermined thickness of 10% or more of the height H of the internal space 15. The flat portion 30 extends from the first wick portion 21 toward the side inner surface 18 while maintaining a predetermined thickness, so that the flat portion 30 has a substantially flat shape.

In the above cross section, the ratio of W1, representing the width of the second wick portion 22, with respect to the sum of W1, representing the width of the second wick portion 22, and W2, representing the width from an end 31 of the second wick portion 22 in the width direction W of the internal space 15 to the inner surface, facing the end 31 of the second wick portion 22, of the container 10 (the side inner surface 18 of the container 10 in FIG. 2), is not particularly limited. Here, the ratio is 50% or more in the heat pipe 1. On the other hand, in the heat pipe 1, the end 31 of the second wick portion 22 is not in contact with the side inner surface 18 of the container 10. Therefore, the ratio of W1, representing the width of the second wick portion 22, with respect to the sum of dimensions of W1, representing the width of the second wick portion 22, and W2, representing the width from the end 31 of the second wick portion 22 to the side inner surface 18 facing the end 31, is less than 100%.

Thus, the end 31 of the second wick portion 22 is not in contact with the side inner surface 18 of the container 10. So, the second wick portion 22, including the flat portion 30, does not extend to the side inner surface 18 of the container 10, and the end 31 of the second wick portion 22 faces the side inner surface 18 with a predetermined interval. Therefore, the other inner surface 17 has a region that is in contact with neither the first wick portion 21 nor the second wick portion 22, and this region is exposed to the internal space 15.

The thickness of the flat portion 30 may be substantially the same in the longitudinal direction of the container 10, or may vary depending on the region of the container 10 in the longitudinal direction. When the thickness of the flat portion 30 varies depending on the region of the container 10 in the longitudinal direction, the thickness of the flat portion 30 in the evaporator portion where the container 10 is thermally connected to the heating element 100 is preferably greater than the thickness of the flat portion 30 in the condenser portion where the container 10 is thermally connected to the unit configured to exchange heat (not shown), in the point in which the capillary force of the second wick portion 22 in the evaporator portion improves and the characteristics of circular current, of the working fluid in liquid-phase, from the condenser portion to the evaporator portion improves.

As shown in FIG. 2, the wick structure 20 has gradual change portions 40, where the thickness of the wick structure 20 continuously reduce in the width direction W of the internal space 15 of the container 10, between the top portion 23 of the first wick portion 21 and the flat portions 30. Each of the gradual change portions 40 is formed across the first wick portion 21 and the second wick portion 22, and the thickness of the wick structure 20 reduces as progress from the first wick portion 21 toward the second wick portion 22. In the width direction W of the internal space 15 of the container 10, the change rate in the thickness of the wick structure 20 at the gradual change portion 40 is greater than the change rate in the thickness of the wick structure 20 at the flat portion 30.

In the cross section, the ratio of the cross-sectional area of the second wick portion 22 to the cross-sectional area of the first wick portion 21 is not particularly limited. However, in the heat pipe 1, from the point of sufficiently providing the vapor flow path 50 through which the working fluid in gas-phase flows and reliably preventing the working fluid in liquid-phase from accumulating, it is preferable to be 1.0% or more and 50% or less, and it is particularly preferable to be 10% or more and 30% or less.

Of the internal space 15 of the container 10, the internal space 15 that is not occupied by the wick structure 20 is a vapor flow path 50 through which the working fluid in gas-phase flows. The wick structure 20 extends in the heat transport direction of the heat pipe 1, and the vapor flow path 50 correspondingly extends in the heat transport direction of the heat pipe 1.

In the above cross section, the ratio of the cross-sectional area of the internal space 15 of the container 10 not occupied by the wick structure 20 (vapor flow path 50) with respect to the cross-sectional area of the wick structure 20 is not particularly limited. However, in the heat pipe 1, from the point of being capable of improving the flow characteristics of the working fluid in liquid-phase and the flow characteristics of the working fluid in gas-phase in a well-balanced manner, it is preferable to be 15% or more and 65% or less, and it is particularly preferable to be 20% or more and 60% or less. More specifically, in the heat pipe 1, the ratio of the cross-sectional area of the internal space 15 of the container 10 not occupied by the wick structure 20 with respect to the cross-sectional area of the wick structure 20 is 30% or more and 50% or less.

The material of the container 10 is not particularly limited, and examples include metals such as copper and copper alloys from the point of excellent thermal conductivity, aluminum and aluminum alloys from the point of lightness, and stainless steel from the point of improvement in mechanical strength. Further, tin, tin alloys, titanium, titanium alloys, nickel, nickel alloys, and the like may be used depending on the use conditions of the heat pipe 1.

As the wick structures, examples include, for example, a sintered body made of powder containing metal powder. Specific examples include a sintered body of metal powder such as copper powder and stainless steel powder, and a sintered body of mixture powder of copper powder and carbon powder. The first wick portion 21 and the second wick portion 22 may be made of powder of the same material type, or may be made of powder of different material types. In addition, the average particle size of the powder in the first wick portion 21 and the second wick portion 22 may be the same or may be different. The average primary particle diameter of the powder containing metal powder, which is the raw material of the sintered body, can be appropriately selected depending on the capillary force and the characteristics of circular current of the working fluid in liquid-phase required for the wick structure 20 and the like. The examples includes, for example, 50 μm or more and 100 μm or less.

Also, the working fluid enclosed in the container 10 can be appropriately selected according to the material of the container 10, and examples include, for example, water, CFC substitutes, perfluorocarbons, and cyclopentane and the like.

Next, an example of a method of manufacturing the heat pipe of the present disclosure will be described. The method of manufacturing the heat pipe of the present disclosure is not particularly limited. For example, a sintered body in which the wick structure 20 is powder can be manufactured by using a core rod provided with a cut-out portion in a predetermined shape for filling powder, which is the raw material for the wick structure 20. Specifically, for example, the core rod having the above shape is inserted from the one end portion to the other end portion in the longitudinal direction of a circular tubular member. A gap portion based on the cut-out portion is formed between the inner wall surface of the tubular member and the outer surface of the core rod. A predetermined amount of powder, which is the raw material of the wick structure 20, is filled into the gap portion from the end portion of the tubular member. The tubular material filled with the powder is heat-treated, the core rod is pulled out from the tubular material, and the tubular member is subjected to flattening processing. When the tubular member is subjected to flattening processing, the wick structure 20 is formed from the powder filled in the cut-out portion.

Next, the heat transport mechanism of the heat pipe 1 according to the first example embodiment of the present disclosure will be described. In the heat pipe 1, for example, the heating element 100 is thermally connected to the one end portion 11, and thereby the one end portion 11 functions as an evaporator portion (heat receiving portion). Further, the unit configured to exchange heat is thermally connected to the other end portion 13 and thereby the other end portion 13 functions as a condenser portion (radiating portion). A central portion 19 positioned between the one end portion 11 and the other end portion 13 functions as a heat insulating portion. When the working fluid receives heat from the heating element 100 at the evaporator portion of the heat pipe 1, the working fluid undergoes a phase change from the liquid-phase to the gas-phase. The working fluid that has undergone a phase change to the gas-phase flows through the vapor flow path 50 in the longitudinal direction of the container 10 from the evaporator portion to the condenser portion (in the heat pipe 1, from the one end portion 11 to the other end portion 13). Thereby heat from the heating element 100 is transported from the evaporator portion to the condenser portion. The heat from the heating element 100 transported from the evaporator portion to the condenser portion is released as latent heat by the phase change of the working fluid in gas-phase to the liquid-phase in the condenser portion provided with the unit configured to exchange heat. The latent heat released in the condenser portion is released from the condenser portion to the external environment of the heat pipe 1 by the unit configured to exchange heat provided in the condenser portion. The working fluid that has undergone a phase change to a liquid-phase in the condenser portion is returned on circular current from the condenser portion to the insulating portion by the capillary force of the wick structure 20.

In the heat pipe 1 according to the first example embodiment of the present disclosure, the wick structure 20 has the first wick portion 21 with a thickness of 50% or more of the height H of the internal space 15 of the container 10, and thereby has excellent characteristics of circular current, of the working fluid in liquid-phase, from the condenser portion to the evaporator portion. Further, each of the second wick portions 22, which extends outward from the first wick portion 21 and has a thickness of less than 50% of the height H of the internal space 15 of the container 10, has a flat portion 30 extending in the width direction W of the internal space 15 of the container 10. Thereby, the vapor flow path 50 through which the working fluid in gas-phase flows is sufficiently provided, and capillary force of the flat portion 30 causes the working fluid in liquid-phase, which accumulates at the end portion in the width direction W of the internal space 15 of the container 10, to be absorbed by the wick structure 20. Therefore, the second wick portion 22 having the flat portion 30 makes it possible to prevent the working fluid in liquid-phase from accumulating at the end portion in the width direction W of the internal space 15 of the container 10, in the condenser portion of the heat pipe 1. From the above, the heat pipe 1 has excellent flow characteristics of the working fluid, exhibits excellent heat transport characteristics, and is capable of preventing abnormal noise from being generated when the working fluid flows even if the installation posture of the electric or electronic device equipped with the heat pipe 1 is changed.

Further, the second wick portion 22 has the flat portion 30 extending in the width direction W of the internal space 15 of the container 10, so that the evaporation area of working fluid in the evaporator portion increases and the thermal resistance can be reduced. In addition, the heat pipe 1 can prevent the working fluid in liquid-phase from accumulating in the condenser portion of the heat pipe 1, so that the heat pipe 1 can cause the part from the one end portion 11 to the other end portion 13 of the container 10 to reliably contribute to heat transport.

Further, in the heat pipe 1, a region of the one inner surface 16, which is not in contact with the first wick portion 21, and the side inner surface 18 have no wick structure formed and are exposed to the internal space 15, so that the vapor flow path 50 is sufficiently provided and the working fluid in gas-phase can smoothly flow.

Further, in the heat pipe 1, the first wick portion 21 has a top portion 23 in contact with one inner surface 16 of the container 10 and a bottom portion 24 in contact with the other inner surface 17. In other words, the first wick portion 21 has a region having a thickness of 100% with respect to the height H of the internal space 15 of the container 10. Therefore, characteristics of circular current, of the working fluid in liquid-phase, from the condenser portion to the evaporator portion is excellent.

In the heat pipe 1, the ratio of W1, representing the width of the second wick portion 22, with respect to the sum of W1, representing the width of the second wick portion 22, and W2, representing the width from the end 31 of the second wick portion 22 to the side inner surface 18 facing the end 31, is 50% or more. This makes it possible to more reliably prevent the working fluid in liquid-phase from accumulating at the end portion in the width direction W of the internal space 15 of the container 10.

In the heat pipe 1, the end 31 of the second wick portion 22 is not in contact with the side inner surface 18 of the container facing the end 31 of the second wick portion 22. Therefore, the vapor flow path 50 is provided more reliably, and the flow characteristics of the working fluid in gas-phase further improves.

In the heat pipe 1, the ratio of the cross-sectional area of the second wick portion 22 to the cross-sectional area of the first wick portion 21 is 1.0% or more and 50% or less. Therefore, excellent flow characteristics of the working fluid and prevention of abnormal noise when the working fluid flows improves in a well-balanced manner.

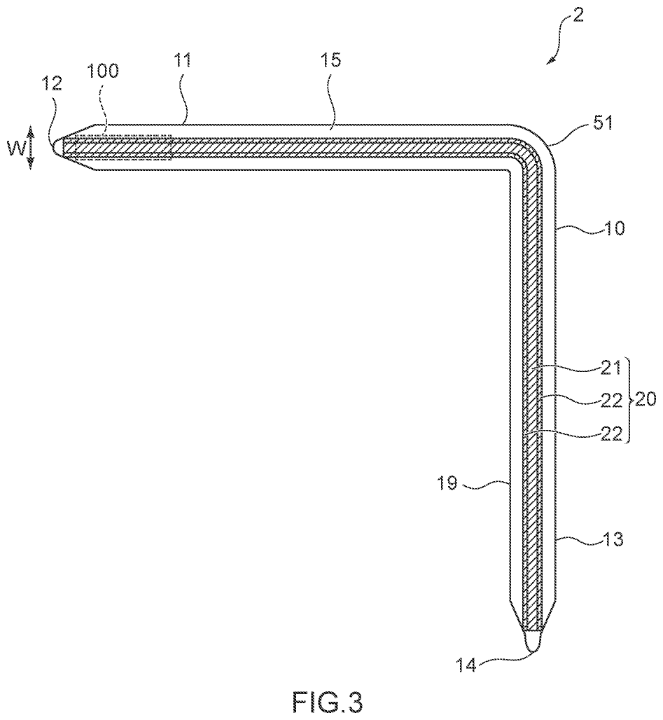

Next, a second example embodiment of the heat pipe of the present disclosure will be described. Note that, since the heat pipe according to the second embodiment has the main components in common with the heat pipe according to the first example embodiment, the same components are described using the same reference numerals and characters. FIG. 3 is an explanatory view showing an outline of a cross section in the longitudinal direction of the heat pipe according to the second example embodiment of the present disclosure.

In the heat pipe 1 according to the first example embodiment, the shape of the container 10 in the longitudinal direction is linear. Instead of this, as shown in FIG. 3, in a heat pipe 2 according to the second example embodiment, the shape of the container 10 in the longitudinal direction is a shape having a curved portion 51. Specifically, in the heat pipe 2, the container 10 is L-shaped with one curved portion 51.

The heat pipe 2, in which the container 10 is L-shaped, can prevent the working fluid in liquid-phase from accumulating at the end portion in the width direction of the internal space 15 of the container 10, in the condenser portion of the heat pipe 2. From the above, the heat pipe 2 also has excellent flow characteristics of the working fluid, exhibits excellent heat transport characteristics, and is capable of preventing abnormal noise from being generated when the working fluid flows even if the installation posture of the electric or electronic device equipped with the heat pipe 2 is changed.

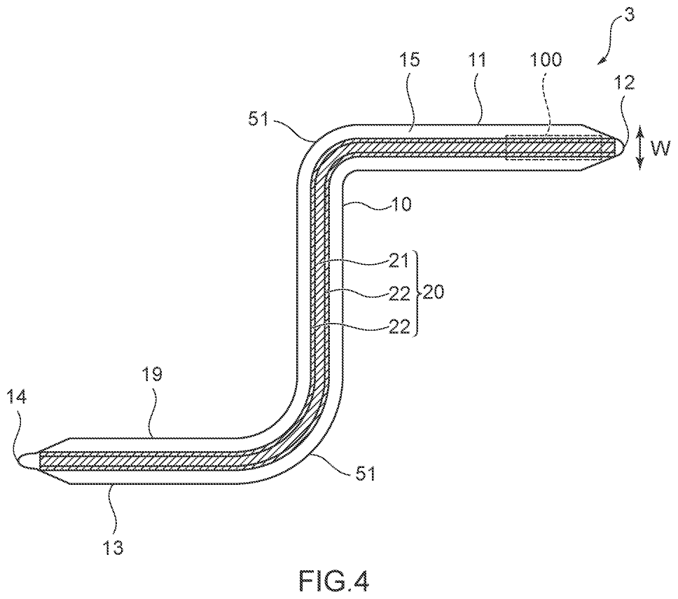

Next, a third example embodiment of the heat pipe of the present disclosure will be described. Note that, since the heat pipe according to the third example embodiment has the main components in common with the heat pipe according to the first and second example embodiments, the same components are described using the same reference numerals and characters. FIG. 4 is an explanatory view showing an outline of a cross section in the longitudinal direction of a heat pipe according to the third example embodiment of the present disclosure.

In the heat pipe 1 according to the first example embodiment, the shape of the container 10 in the longitudinal direction is linear. Instead of this, as shown in FIG. 4, in a heat pipe 3 according to the third example embodiment, the shape of the container 10 in the longitudinal direction is a shape having a plurality of curved portions 51 (two in the heat pipe 3).

The heat pipe 3, in which the container 10 has two curved portions 51, can also prevent the working fluid in liquid-phase from accumulating at the end portion in the width direction of the internal space 15 of the container 10, in the condenser portion of the heat pipe 3. From the above, the heat pipe 3 also has excellent flow characteristics of the working fluid, exhibits excellent heat transport characteristics, and is capable of preventing abnormal noise from being generated when the working fluid flows even if the installation posture of the electric or electronic device equipped with the heat pipe 3 is changed.

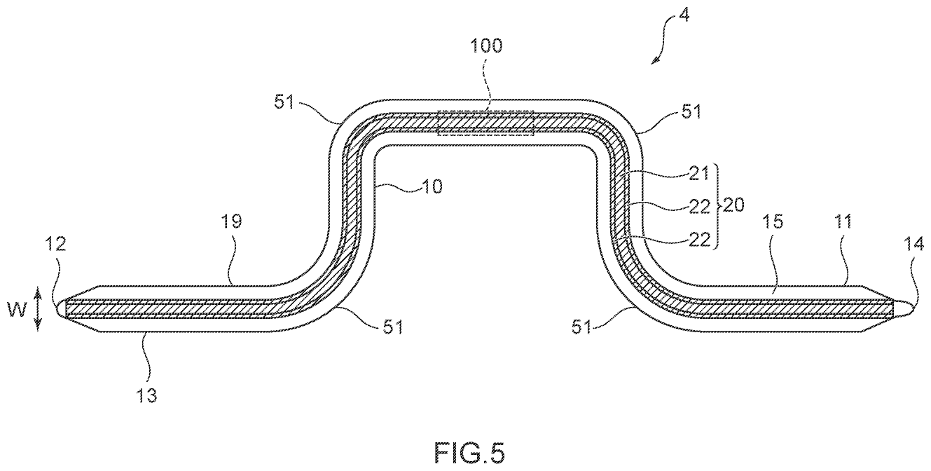

Next, a fourth example embodiment of the heat pipe of the present disclosure will be described. Note that, since the heat pipe according to the fourth example embodiment has the main components in common with the heat pipe according to the first to third example embodiments, the same components are described using the same reference numerals and characters. FIG. 5 is an explanatory view showing an outline of a cross section in the longitudinal direction of a heat pipe according to the fourth example embodiment of the present disclosure.

In the heat pipe 1 according to the first example embodiment, the shape of the container 10 in the longitudinal direction is linear. Instead of this, as shown in FIG. 5, in a heat pipe 4 according to the fourth example embodiment, the shape of the container 10 in the longitudinal direction is a shape having a plurality of curved portions 51 (four in the heat pipe 4). Further, in the heat pipe 1 according to the first example embodiment, the heating element 100 is thermally connected to the one end portion 11 of the container 10. Instead of this, as shown in FIG. 5, in the heat pipe 4 according to the fourth example embodiment, a heating element 100 is thermally connected to a central portion 19 of the container 10, and the central portion 19 of the container 10 functions as an evaporator portion (heat receiving portion). As described above, in the heat pipe 4, the one end portion 11 and the other end portion 13 of the container 10 function as condenser portions (radiating portions).

the heat pipe 4, in which the container 10 has the shape having four curved portions 51 and has the heating element 100 thermally connected to the central portion 19 of the container 10, can also prevent the working fluid in liquid-phase from accumulating at the end portions in the width direction of the internal space 15 of the container 10, in the condenser portions of the heat pipe 4. From the above, the heat pipe 4 also has excellent flow characteristics of the working fluid, exhibits excellent heat transport characteristics, and is capable of preventing abnormal noise from being generated when the working fluid flows even if the installation posture of the electric or electronic device equipped with the heat pipe 4 is changed.

Next, another example embodiment of the heat pipe of the present disclosure will be described. In each of the above example embodiments of the heat pipe, in a cross section perpendicular to the longitudinal direction of the container 10, the wick structure 20 has the first wick portion 21 having a thickness of 50% or more of the height H of the internal space 15 of the container 10, and a second wick portion 22 having a thickness less than 50% of the height H of the internal space 15 of the container 10. In the cross section above, if the first wick portion 21 is thicker than the second wick portion 22 (the second wick portion 22 is thinner than the first wick portion 21), the thicknesses of the first wick portion 21 and the second wick portion 22 with respect to the height H of the internal space 15 are not particularly limited. Further, in each of the above example embodiments of the heat pipe, the ratio of W1, representing the width of the second wick portion 22, with respect to the sum of W1, representing the width of the second wick portion 22, and W2, representing the width from the end 31 of the second wick portion 22 to the side inner surface 18 facing the end 31, is 50% or more and less than 100%. Instead of this, the ratio may be, for example, 30% or more and less than 50%.

In each of the above example embodiments of the heat pipe, the top portion 23 of the first wick portion 21 is in contact with one inner surface 16. Instead of this, an aspect may be such that the top portion 23 of the first wick portion 21 is not in contact with the inner surface of the container 10 depending on the use conditions of the heat pipe. In other words, if the first wick portion 21 has a thickness of 50% or more of the height H of the internal space 15 of the container 10, the first wick portion 21 may have a thickness less than 100% of the height H of the internal space 15 of the container 10.

The heat pipe of the present disclosure has excellent flow characteristics of the working fluid, exhibits excellent heat transport characteristics, and is capable of preventing abnormal noise from being generated when the working fluid flows. Therefore, the heat pipe of the present disclosure has a high utility value in the field of cooling electronic components such as semiconductor elements installed in portable electric and electronic devices whose installation postures are likely to change.

What is claimed is:

1. A heat pipe comprising:
a container being a tubular body, the container having an end surface of one end portion and an end surface of another end portion, the end surfaces each being sealed;
a wick structure provided inside the container; and
a working fluid enclosed inside the container,
wherein the wick structure includes a first wick portion and a second wick portion in at least one cross section perpendicular to a longitudinal direction of the container, the second wick portion being integral with the first wick portion, the second wick portion extending outward from the first wick portion, the second wick portion being thinner than the first wick portion, and
the second wick portion includes a flat portion extending in a direction perpendicular to a height direction of an internal space of the container.

2. The heat pipe according to claim 1, wherein
the first wick portion has a thickness of 50% or more of a height of the internal space of the container, and the second wick portion has a thickness of less than 50% of the height of the internal space of the container.

3. The heat pipe according to claim 1, wherein at least a partial area of the container has a flattened portion subjected to flattening processing.

4. The heat pipe according to claim 3, wherein
the flattened portion includes one inner surface and another inner surface facing the one inner surface in the height direction of the internal space of the container, and in the one cross section, the first wick portion has a top portion in contact with the one inner surface and a bottom portion in contact with the other inner surface.

5. The heat pipe according to claim 1, wherein
in the one cross section, the wick structure has a gradual change portion between a top portion of the first wick portion and the flat portion, the gradual change portion being a portion in which thickness of the wick structure continuously reduces in a direction perpendicular to the height direction of the internal space of the container.

6. The heat pipe according to claim 2, wherein
in the one cross section, the wick structure has a gradual change portion between a top portion of the first wick portion and the flat portion, the gradual change portion being a portion in which thickness of the wick structure continuously reduces in a direction perpendicular to the height direction of the internal space of the container.

7. The heat pipe according to claim 4, wherein
in the one cross section, the wick structure has a gradual change portion between a top portion of the first wick portion and the flat portion, the gradual change portion being a portion in which thickness of the wick structure continuously reduces in a direction perpendicular to the height direction of the internal space of the container.

8. The heat pipe according to claim 1, wherein
in the one cross section, a ratio of a width of the second wick portion with respect to a sum of the width of the second wick portion and a width from an end of the second wick portion to an inner surface of the container is 50% or more, the inner surface facing the end of the second wick portion which is in contact with the inner surface or is not in contact with the inner surface.

9. The heat pipe according to claim 2, wherein
in the one cross section, a ratio of a width of the second wick portion with respect to a sum of the width of the second wick portion and a width from an end of the second wick portion to an inner surface of the container is 50% or more, the inner surface facing the end of the second wick portion which is in contact with the inner surface or is not in contact with the inner surface.

10. The heat pipe according to claim 4, wherein
in the one cross section, a ratio of a width of the second wick portion with respect to a sum of the width of the second wick portion and a width from an end of the second wick portion to an inner surface of the container is 50% or more, the inner surface facing the end of the second wick portion which is in contact with the inner surface or is not in contact with the inner surface.

11. The heat pipe according to claim 5, wherein
in the one cross section, a ratio of a width of the second wick portion with respect to a sum of the width of the second wick portion and a width from an end of the second wick portion to an inner surface of the container is 50% or more, the inner surface facing the end of the second wick portion which is in contact with the inner surface or is not in contact with the inner surface.

12. The heat pipe according to claim 1, wherein
an end of the second wick portion is not in contact with an inner surface of the container facing the end of the second wick portion.

13. The heat pipe according to claim 1, wherein
in the one cross section, a ratio of a cross-sectional area of the second wick portion to a cross-sectional area of the first wick portion is 1.0% or more and 50% or less.

14. The heat pipe according to claim 1, wherein
the container has an evaporator portion and a condenser portion, and a thickness of the flat portion in the evaporator portion is thicker than a thickness of the flat portion in the condenser portion, the evaporator portion being thermally connected to a heating element, the condenser portion being thermally connected to a unit configured to exchange heat.

15. The heat pipe according to claim 2, wherein
the container has an evaporator portion and a condenser portion, and a thickness of the flat portion in the evaporator portion is thicker than a thickness of the flat portion in the condenser portion, the evaporator portion being thermally connected to a heating element, the condenser portion being thermally connected to a unit configured to exchange heat.

16. The heat pipe according to claim 4, wherein
the container has an evaporator portion and a condenser portion, and a thickness of the flat portion in the evaporator portion is thicker than a thickness of the flat portion in the condenser portion, the evaporator portion being thermally connected to a heating element, the condenser portion being thermally connected to a unit configured to exchange heat.

17. The heat pipe according to claim 5, wherein
the container has an evaporator portion and a condenser portion, and a thickness of the flat portion in the evaporator portion is thicker than a thickness of the flat portion in the condenser portion, the evaporator portion being thermally connected to a heating element, the condenser portion being thermally connected to a unit configured to exchange heat.

18. The heat pipe according to claim 1, wherein
in the one cross section, a ratio of a cross-sectional area of the internal space of the container not occupied by the wick structure with respect to a cross-sectional area of the wick structure is 15% or more and 65% or less.

19. The heat pipe according to claim 1, wherein
the wick structure is a sintered body of metal powder.
